(19) United States
(12) Patent Application Publication
(10) Pub. No.: US 2006/0152136 A1
(43) Pub. Date: Jul. 13, 2006

(54) Transparent conductive laminate and display

(76) Inventors: Hideo Fujikake, Tokyo (JP); Hiroto Sato, Tokyo (JP); Naoto Abe, Ohmihachiman-shi (JP)

Correspondence Address: Allan M Wheatcraft;W L Gore & ASSOCIATES INC, 551 Paper Mill Road, Post Office Box 9206, Neward, DE, 19714-9206, US

(21) Appl. No.: 10/530,007

(22) PCT Filed: Oct. 2, 2003
(86) PCT No.: PCT/JP03/12679

§ 371 Date: Oct. 12, 2005

(30) Foreign Application Priority Data
Oct. 2, 2002 (JP) 2002-290282

(51) Int. Cl. H05B 33/22; H01L 51/50

(52) U.S. Cl. 313/503; 313/506; 313/509

(57) ABSTRACT

A transparent electroconductive film characterized in comprising a laminate having a three-layered structure in which a transparent electroconductive layer is formed via a transparent gas barrier layer on one face of a transparent, fluorine-containing resin film.

### FIELD OF THE INVENTION

The present invention relates to a transparent electroconductive film, and to a display device, and more particularly, to a transparent electroconductive film having high heat resistance, low elasticity, and low moisture absorbance, as well as excellent solvent resistance, weatherability, and other characteristics

### BACKGROUND OF THE INVENTION

Glass provided with a transparent electrode has mainly been used as the transparent substrate for holding the display medium in the display panels of liquid crystal display devices, electrophoretic display devices, electrodeposition display devices, organic electroluminescent display devices, dispersion-type inorganic electroluminescent display devices, and other display devices. However, since transparent resin films are lightweight, thin, and resistant to breakage, their use in the substrates of these display devices is now being developed.

Conventional transparent resin films used in transparent electrodes include polycarbonates (PC), polyarylates (PAR), polyether sulfones (PES), polyethylene terephthalate (PET), and other materials having excellent light transmissivity and other optical characteristics. A transparent substrate that uses these materials is generally made up of a transparent resin film on which a gas barrier layer and transparent electroconductive layer are formed. Known examples thereof are described in JP (Kokai) No. 6-196023 (Prior Art 1), 8-323912 (Prior Art 2), 10-24520 (Prior Art 3), and other publications. Fluorine film substrates on which a transparent electroconductive layer is formed are also described in JP (Kokai) No. 57-88430 (Prior Art 4) and other publications as examples of transparent resin films other than those described above.

The method of manufacturing a transparent substrate or display device that uses a transparent resin film is as described below. After attaching a transparent electroconductive layer of a metal oxide film to a transparent resin film by means of vacuum deposition or sputtering involving heating of the substrate, a resist fluid is applied thereon by means of roll coating, spin coating, or the like, and the product is masked using patterned glass. The product is then exposed with the help of ultraviolet rays and developed, the light-sensitive portions are removed, and the transparent electroconductive film is subjected to etching treatment. After etching, the resist is peeled off using NaOH or another alkali, and the alkali component is thoroughly rinsed off.

In the case of a liquid crystal display device, a polyimide or other resin for forming an orientation film is applied to the transparent substrate on which the transparent electrode is formed, and after high-temperature calcination, rubbing treatment is performed. A spacer material is then sprayed on the panel face of one of the substrates, a seal material is printed on the peripheral portion of the substrate, and both substrates are pressed together. Liquid crystal fluid is finally vacuum-injected into the gap between the attached substrates, and a display panel is fabricated.

In the case of electrophoretic display devices and electrodeposition display devices, ink containing electrophoretic pigment particles, or an electrolyte solution containing metal ions is sandwiched between the substrates to form a panel.

Since there is not necessarily a need to sandwich the display medium between two transparent substrates in other self-luminous displays, the display panels thereof are constructed as a result of attaching a luminous material to a single transparent substrate.

However, conventional display devices that use a transparent resin film have such drawbacks as the following.

(1) From the perspective of the mechanical characteristics of the transparent substrate, when the flexural modulus is used as an indicator thereof, transparent resin films having a flexural modulus of 200 kg/mm² or higher have been preferred for use in conventional transparent substrates, but these films have poor flexibility, and application thereof to a curved display is difficult. Also because of poor flexibility, these films cannot be applied in roll-type display devices having excellent portability or storage properties.

(2) A high-temperature process is needed when a transparent electrode or orientation film is formed on a transparent resin film (for example, the substrate must be heated to 100° C. or higher in formation of a transparent electroconductive film having low electrical resistance, and heat treatment at about 200° C. is essential to the formation of the orientation film needed in the case of a liquid crystal display), but a transparent resin film has low heat resistance, and the smoothness thereof is degraded as a result of decreased surface resistance (rupturing/breaking of the transparent electroconductive layer occurs in extreme cases), warping, and other physical changes. As a result, the manufacturing yield of the display device is markedly reduced.

(3) Acids, alkali, various organic solvents, and the like are used in display panel assembly, transparent electrode patterning, orientation film formation, and various cleaning steps, but the transparency of a transparent resin film that has poor solvent resistance is adversely affected by dissolution or deterioration (whitening). Brightness, contrast, or other display characteristics are thereby reduced.

(4) A transparent substrate in which the conventional transparent resin film substrate is used has inadequate gas barrier properties, and ingression of air is a factor that causes defects in the display device. Since the display medium has high moisture absorbance and is easily affected by moisture in the air, the display medium degrades, and the reliability of the display device is reduced.

### SUMMARY OF THE INVENTION

An object of the present invention is to provide a transparent electroconductive film having high heat resistance, low elasticity, and low moisture absorbance, as well as excellent solvent resistance, weatherability, and other characteristics, and to provide a display device that uses this film.

The inventors perfected the present invention as a result of concentrated investigation aimed at overcoming the foregoing drawbacks.

Specifically, the present invention provides a transparent electroconductive film, characterized in comprising a laminate having a three-layered structure in which a transparent electroconductive layer is formed via a transparent gas barrier layer on one face of a transparent, fluorine-containing resin film.

The invention also provides a transparent electroconductive film as described above, characterized in that a surface treatment for enhancing the adhesion of the film is performed on the face of the transparent, fluorine-containing resin film on the side of the transparent gas barrier layer.

In another aspect, the invention provides a transparent electroconductive film, characterized in comprising a laminate having a three-layered structure in which a transparent gas barrier layer is formed on one face of a transparent, fluorine-containing resin film, and a transparent electroconductive layer is formed on the other face.

The invention also provides a transparent electroconductive film as described above, characterized in that a surface treatment for enhancing the adhesion of the film is performed on both faces of the transparent, fluorine-containing resin film.

The invention also provides a transparent electroconductive film as described above, characterized in that a primer layer is formed on the surface-treated face of the transparent, fluorine-containing resin film.

The invention also provides a transparent electroconductive film as described above, characterized in having a flexural modulus of 1 to 100 kg/mm².

The invention also provides a transparent electroconductive film as described above, characterized in having light transmittance of 80% or higher at a wavelength of 550 nm after heat treatment, and in having no change in appearance due to heat treatment.

The invention also provides a transparent electroconductive film as described above, characterized in that the moisture absorbance of the transparent, fluorine-containing resin film is 0.1% or less.

In another aspect, the invention provides a display device having a structure in which a display medium whose overall form is gaseous, liquid, or solid is held between transparent substrates, wherein the display device is characterized in that at least one of the transparent substrates comprises the electroconductive film as described above.

The invention also provides a display device as described above, characterized in that the display medium comprises liquid crystal.

The invention also provides a display device as described above, characterized in having a polymer structure between the substrates, for maintaining a constant spacing between the substrates.

The invention also provides a display device as described above, characterized in that the display medium has electrophoretic effects whereby non-transparent particles are shifted or rotated as a result of the application of a voltage, and the state of absorbance of external light changes.

The invention also provides a display device as described above, characterized in that the display medium has electrodeposition effects whereby metal ionization/deposition is controlled in an electrolyte solution as a result of a current injection, and the state of absorbance of external light changes.

The invention also provides a display device as described above, characterized in that the display medium comprises an organic thin film or a resin film with a dispersed inorganic phosphor having electroluminescent effects whereby light is emitted as a result of a current injection or a voltage application.

In another aspect, the invention provides a display device having a structure in which a display medium comprising a thin film is laminated on a transparent substrate, wherein the display device is characterized in that the transparent substrate comprises the transparent electroconductive film as described above.

### DESCRIPTION OF THE DRAWINGS

FIG. 1 is a structural diagram of an example of the transparent electroconductive film of the present invention;

FIG. 2 is a structural diagram of another example of the transparent electroconductive film of the present invention;

FIG. 3 is a structural diagram of yet another example of the transparent electroconductive film of the present invention;

FIG. 4 is a structural diagram of still another example of the transparent electroconductive film of the present invention;

FIG. 5 is a schematic cross-sectional diagram of an example of the display device of the present invention; and

FIG. 6 is a diagram showing the relationship between applied voltage and light transmittance in the display device of the present invention.

### DETAILED DESCRIPTION OF THE INVENTION

The transparent electroconductive film of the present invention (hereinafter referred to simply as “film”) has a transparent, fluorine-containing resin film as the base film thereof. Various types of known films can be used for this type of film. Examples of such materials include polytetrafluoroethylene (PTFE); copolymers of tetrafluoroethylene and hexafluoropropylene (FEP); perfluoroalkoxy resins (PFA) composed of copolymers of tetrafluoroethylene and perfluoroalkyl vinyl ether, copolymers of tetrafluoroethylene, perfluoroalkyl vinyl ether, and hexafluoropropylene (EPE); copolymers of tetrafluoroethylene and ethylene or propylene (ETFE); polychlorotrifluoroethylene resin (PCTFE); copolymers of ethylene and chlorotrifluoroethylene (ECTFE); vinylidene fluoride resin (PVDF); or films composed of one or more fluorine-containing resins such as polyvinyl fluoride (PVF).

The aforementioned transparent, fluorine-containing resin film has a thickness of 5 to 500 μm, and preferably about 20 to 250 μm, and preferably has a light transmissivity of 80% or higher at a wavelength of 550 nm.

The film of the present invention has a transparent electroconductive layer. This transparent electroconductive layer is formed using a conventionally known transparent electroconductive material. Examples of transparent electroconductive materials that are preferred for use in this case include indium oxide-tin oxide (ITO), indium oxide, tin oxide, zinc oxide, antimony oxide, indium oxide-gallium oxide, indium oxide-zinc oxide, indium oxide-aluminum oxide, and other metal oxides. The transparent electroconductive layer is formed by means of CVD, vacuum deposition, ion plating, sputtering, and other techniques using a metal oxide or other inorganic transparent electroconductive material, but when adhesion to the substrate is considered, sputtering methods and ion plating methods are preferred as the method for forming the transparent electroconductive layer, and sputtering methods are particularly preferred.

For a transparent electroconductive film other than that of a metal oxide, a polythiophene resin or other transparent organic electroconductive material may be used to form a thin film coating on a transparent, fluorine-containing resin film by means of spin coating, printing, or the like.

This transparent electroconductive layer has a thickness of 50 to 2000 Å, preferably 100 to 1500 Å. The surface electrical resistance thereof is 10 to 500 Ω/square, preferably 10 to 100 Ω/square.

The film of the present invention contains a transparent gas barrier layer. This transparent gas barrier layer may be formed using a conventionally known gas barrier material. Examples of such gas barrier materials include oxides of silicon, aluminum, magnesium, zinc, zirconium, and other metals, and SiOx (1.5≦x≦2.0) is most preferably used from the perspective of transparency, mechanical characteristics, gas barrier properties, and the like. The ratio of oxygen with respect to silicon in the silicon oxide used herein is confirmed with the help of X-ray photoelectron spectroscopy, Auger electron spectroscopy, or another method.

The aforementioned transparent gas barrier layer has a thickness of 50 to 2000 Å, preferably 100 to 1000 Å.

In the present invention, a conventionally known surface treatment may be performed on one or both faces of the fluorine-containing resin film in order to enhance adhesion with the layers. This type of surface treatment may include ultraviolet irradiation treatment, plasma treatment, corona discharge treatment, and the like.

In the present invention, a primer layer may be formed on one or both faces of the fluorine-containing resin film in order to enhance adhesion with the layers. In this case, the primer layer may be formed on the untreated surface of the fluorine-containing resin film, but formation thereof on the treated surface is preferred.

The primer layer is formed using a conventionally known primer material. Various types of adhesive materials may be used as this type of material, and examples thereof include epoxy resin, acrylic resin, polyester resin, polyamide resin, urethane resin, phenol resin, silicone resin, polysilane resin, fluororesin, ethylene-vinyl alcohol resin, vinyl chloride-vinyl acetate resin, and the like.

This primer layer has a thickness of 0.01 to 20 μm, preferably 0.1 to 20 μm.

The transparent electroconductive film of the present invention is manufactured with the help of a conventionally known method, and the manufacturing method is not subject to any particular limitation as long as the method yields the desired laminate.

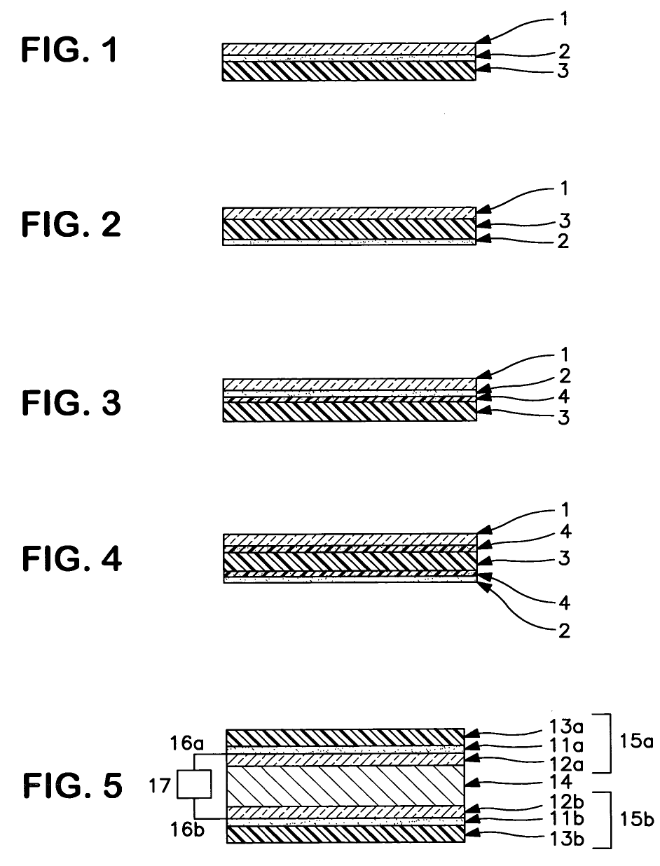

Diagrams of the layer structure of the transparent electroconductive film of the present invention are shown in FIGS. 1 through 4.

In these figures, 1 indicates the transparent electroconductive layer, 2 indicates the transparent gas barrier layer, 3 indicates the transparent, fluorine-containing resin film, and 4 indicates the primer layer.

The primer layer 4 is formed on the surface of the transparent, fluorine-containing resin film that is treated to enhance adhesion.

The transparent electroconductive film of the present invention has a flexural modulus of 1 to 100 kg/mm², preferably 10 to 50 kg/mm².

The light transmittance thereof at a wavelength of 550 nm is 80% or higher, preferably 85% or higher. The moisture absorbance thereof is 0.1% or less, preferably 0.01% or less. The thickness thereof is 5 to 500 μm, preferably 20 to 250 μm. The conductivity thereof is indicated by the surface resistance, and is 10 to 500 Ω/square, preferably 10 to 100 Ω/square.

The film of the present invention has a light transmittance of 80% or higher at a wavelength of 550 nm after being heat treated for two hours in a vacuum at 220° C., and there is no change in the appearance thereof due to heat treatment.

The transparent electroconductive film of the present invention may be used in at least one of the transparent substrates in a conventionally known display device having a structure in which a display medium whose overall form is gaseous, liquid, or solid is held between transparent substrates.

The transparent electroconductive film of the present invention may also be used as a transparent substrate in a conventionally known display device having a structure in which a display medium composed of a thin film is laminated on a transparent substrate.

The display medium used in the display device of the present invention may be one of various conventionally known types whose overall form is gaseous (in which solid particles or liquid particles are contained in a gas), liquid (in which solid particles are contained in a liquid), or solid (in which liquid particles or solid particles are contained in a solid), and is not subject to any

Liquid crystal in which incident light is modulated as a result of the molecular orientation or optical characteristics thereof being altered in response to voltage application can be cited as an example of this type of display medium. In the case of a display device containing this type of liquid crystal, transmissive-type and reflective-type display devices for performing a display operation as a result of modulation of transmitted light and reflected light can be constructed. Nematic liquid crystal, cholesteric liquid crystal, smectic liquid crystal (including ferroelectric liquid crystal capable of high-speed operation), and the like can be used as the liquid crystal material used in such a display device. It is possible to control the initial orientation of liquid crystal molecules into a homeotropic (vertical) orientation, a homogeneous (horizontal) orientation, a spiral orientation, a pie-shaped orientation, a hybrid orientation in which vertical and horizontal orientations are combined, and other orientations as a result of the action of an orientation film (rubbed polyimide resin or the like) provided on the transparent electrode, but this control is not necessarily limited to these orientations.

It is also possible to use a composite film for the display medium in which fine polymer structures (acrylic resin, urethane resin, or the like) are formed in liquid crystal. These polymers assume the role of maintaining the gap between two sheets of transparent substrate; specifically, maintaining a constant thickness in a composite film when the display device is flexed or acted on by an external force. Light polymerization, heat polymerization, phase separation using solvent evaporation, impregnation methods in which liquid crystal is soaked into a porous resin, and other methods are useful as methods for forming a composite film of liquid crystal and a polymer. The polymer can be used in the form of a polymer structure containing droplets of liquid crystal, a mesh, particles, blocks, and various other polymer structures. When there is strong scattering of light by the composite film in a display device that uses a composite film, the intensity of the scattering varies according to the liquid crystal orientation, so optical modulation becomes possible without using a polarizing plate, and a bright display can be obtained.

In the case of a liquid crystal display device, a polarizing plate for aligning the polarization of incident light and exiting light is sometimes necessary, but the polarizing plate can also be integrated with the display device as a result of affixing the polarizing plate to the transparent substrate.

Examples of display media other than liquid crystal include those that contain electrophoretic particles whose absorption of external light varies due to colored or clouded microparticles (pigments or the like) in a liquid or gas sandwiched in a substrate being shifted or rotated in response to the electrostatic force that accompanies the voltage application. In this type of electrophoretic display device that uses these electrophoretic particles, two electrode sheets on which a prescribed electrode pattern for display is formed using ITO or another transparent electroconductive material are provided facing each other, a dispersion in which electrophoretic particles are dispersed in a liquid dispersion medium is sealed between opposite electrodes separated with the help of a spacer, and the periphery of the assembly is sealed.

Additional examples include display media that have electrodeposition effects whereby the ionization/deposition of a metal (silver or the like) is controlled in an electrolyte solution as a result of the current injection from the transparent electroconductive layer, and the state of absorbance of external light is altered.

An organic thin film for emitting light in response to a current injection from the transparent electroconductive layer can also be cited as the display medium. If this organic thin film is used, a flexible organic electroluminescent display device can easily be obtained. The three basic structures that include a single-layer structure, a single hetero structure, and a double hetero structure are the structures used to obtain organic electroluminescence. The single-layer structure is the simplest elemental structure among the three structures, and a single organic layer assumes all the functions of hole transport, electron transport, and luminescence. This structure is often used in polymer organic EL, in which a multilayer structure is difficult to obtain, but since an injected carrier cannot be kept inside the element, optimization of the carrier balance is difficult, and the efficiency thereof compared to other structures is reduced. In a single hetero structure, high luminance and high efficiency are obtained as a result of separating the injection/transport of holes and electrons into two layers. The double hetero structure is the elemental structure in which the separation of functions is most advanced, and the element therein is composed of three layers that include the hole transport layer, the luminescent layer, and the electron transport layer. Electrons and holes are each transported through their corresponding transport layers and are injected into the luminescent layer.

Describing the operational mechanism of organic electroluminescence using an element having a single hetero structure as an example, holes are first injected into the hole transport layer from the positive electrode, and are transported to the electron-transporting luminescent layer interface. Electrons are injected into the electron-transporting luminescent layer from the negative electrode, and are transported through the layer. Although the injected/transported holes and electrons are recombined either in the hole transport layer or in the electron transport layer, which layer becomes the recombination zone is determined by its energy level and charge transporting ability relative to the other. Luminescence is obtained when the organic molecules excited as a result of the recombination of holes and electrons are reduced to the ground state.

If a resin film containing a dispersed inorganic phosphorescent material that emits light in response to the application of an electric field is used as the display medium, a dispersion-type electroluminescent display device can also be obtained. It is sufficient for one of the substrates to be transparent in a reflective liquid crystal display device or an electrophoretic display device that uses external light, or in a self-luminous organic electroluminescent display device or dispersion-type electroluminescent display device. Therefore, two transparent substrates that contain a transparent gas barrier layer, a transparent electroconductive layer, and a fluorine-containing transparent resin film are not necessarily needed, and a single transparent substrate may be used in this case.

FIG. 5 is a structural diagram illustrating the display device of the present invention.

In FIG. 5, 11a and 11b indicate transparent gas barrier layers; 12a and 12b indicate transparent electroconductive layers; 13a and 13b indicate transparent, fluorine-containing resin films; 14 indicates a display medium; 15a and 15b indicate transparent substrates; 16a and 16b indicate lead wires; and 17 indicates a power supply.

Since the display device of the present invention contains a substrate composed of the transparent electroconductive film of the present invention, low elasticity, high heat resistance, solvent resistance, and low moisture absorbance are ensured therein, and the display device is a flexible display device having excellent display characteristics, reliability, and manufacturing yield.

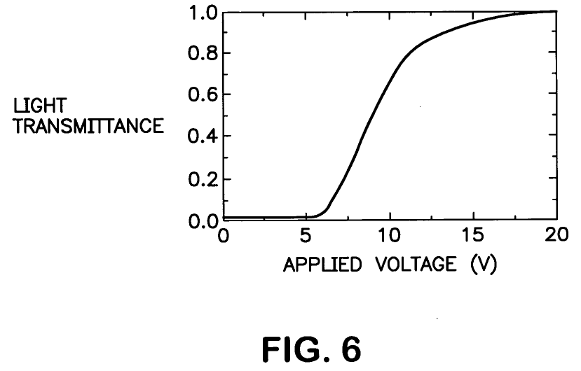

FIG. 6 shows the relationship between applied voltage (V) and transmissivity in a liquid crystal display device obtained as a result of the present invention.

The present invention will be described in further detail hereinafter using working examples. The transparent substrate of the display device was evaluated with the help of the measurement of the following characteristics.

(Total light transmittance) The light transmittance at a wavelength of 550 nm was measured using a UV-2400PC (manufactured by Shimadzu Corp.).

(Surface resistance) Surface resistance was measured with the help of the four-terminal method using a LORESTA-GP MCP-T600 (manufactured by Mitsubishi Chemical Corp.).

(Heat resistance) The physical properties and change in appearance were studied after heating the product for two hours in a dryer at 220° C. and cooling it to room temperature.

(Flexural modulus) A transparent electroconductive substrate for use in measurement of flexural modulus was fabricated by means of layering a silicon oxide layer (film thickness of 100 Å) as a transparent barrier layer and an ITO layer (film thickness of 1500 Å) as a transparent electroconductive layer in sequence with the help of the same method as described in the working examples on a film substrate with a thickness of 3 mm obtained as a result of layering a transparent, fluorine-containing transparent resin film. The flexural modulus of this transparent electroconductive substrate was measured using the procedure according to the JIS K 7121 test method for flexural characteristics.

### WORKING EXAMPLE 1

A fluororesin (NEOFLON™ PFA AP-201) manufactured by Daikin Industries, Ltd. was melted in a twin-screw extruder (screw diameter: 15 mm) and extruded into a film shape with the help of a T-shaped die at the leading end of the extruder (lip length: 150 mm; lip clearance: 0.6 mm; die temperature: 340° C.), the product was cooled, and a transparent, fluorine-containing transparent resin film having a thickness of 200 μm was obtained.

Using the transparent, fluorine-containing transparent resin film thus obtained as the substrate, a silicon oxide layer (film thickness: 100 Å) as a transparent barrier layer and an ITO layer (film thickness: 1500 Å) as a transparent electroconductive layer were formed in sequence on one face thereof by means of sputtering, and a transparent electroconductive substrate for a display device was fabricated. The sputtering conditions were as shown below.

| | |
|---|---|
| (Silicon oxide layer) | |
| Target: | SiO₂ |
| Infusion gas: | Ar and O₂ |
| Sputter vacuum pressure: | 2.0 × 10⁻³ Torr |
| Input power: | 3.0 kW |
| Substrate temperature: | 100° C. |
| (ITO layer) | |
| Target: | ITO (In₂O₃: SnO₂ = 9:1) |
| Infusion gas: | Ar and O₂ |
| Sputter vacuum pressure: | 2.0 × 10⁻³ Torr |
| Input power: | 0.3 kW |
| Substrate temperature: | 100° C. |

### WORKING EXAMPLE 2

A transparent electroconductive substrate for a display device was obtained with the help of the same method as described in Working Example 1, with the exception that PFA (NEOFLON™ PFA FILM AF-0100) manufactured by Daikin Industries, Ltd. having a thickness of 100 μm was used as the transparent, fluorine-containing resin film.

### WORKING EXAMPLE 3

A transparent electroconductive substrate for a display device was obtained with the help of the same method as described in Working Example 1, with the exception that FEP (NEOFLON™ FEP FILM NF-0100) manufactured by Daikin Industries, Ltd. having a thickness of 100 μm was used as the transparent, fluorine-containing resin film.

### COMPARATIVE EXAMPLE 1

The characteristics of a commercially available transparent electroconductive substrate (OTEC, manufactured by Ojitobi (Inc.)) having a thickness of 125 μm were confirmed using PET as the substrate film.

### WORKING EXAMPLE 4

A liquid crystal display device was fabricated using the transparent electroconductive substrate obtained as described in Working Example 1. First, plastic beads (particle diameter: 25 μm) were uniformly dispersed on the transparent electroconductive substrate. A sealant adhesive (epoxy transparent adhesive) was then applied on all sides of the transparent electroconductive substrate. At this time, an injection hole for injection of liquid crystal was opened therein in advance. The transparent electroconductive substrates were then stacked together, the seals were bonded by means of ultraviolet irradiation, and the substrates were affixed to each other. A mixed solution of liquid crystal and ultraviolet-curable monomer (PNM-103, manufactured by Dainippon Ink Inc.) was injected therein from the liquid crystal injection hole, a fine mesh-shaped resin was caused to separate in the liquid crystal by means of irradiation with ultraviolet rays, and a composite film of liquid crystal and resin was formed between the substrates. The results of measuring the relationship between the voltage strength applied between the ITO and the light transmittance are shown in FIG. 6, and high-contrast display operation was confirmed. The liquid crystal display device thus obtained had superior flexibility and could easily be flexed.

The characteristics of the transparent electroconductive substrates for a display device obtained as described in Working Examples 1 through 3 and Comparative Example 1 above are shown in Table 1. The flexural modulus of 200 kg/mm² for the conventional transparent substrate can be reduced to ⅓ thereof or less as a result of using a flexible transparent substrate composed of a transparent gas barrier layer, a transparent electroconductive layer, and a transparent, fluorine-containing resin film, so a high degree of flexibility can also be imparted to the display device. Since a heat-resistant transparent, fluorine-containing resin film is used in the substrate, the drawbacks of reduced light transmittance, increased surface resistance, and substrate deformation due to heat treatment (at 220° C.) are eliminated. Furthermore, since the moisture absorbance is less than 0.1%, it is difficult for moisture in the vacuum to affect the product, and the reliability of the display device is also enhanced. When an acid or base is used in patterning of the transparent electrode and the like, a fluorine-containing transparent resin film has excellent resistance to these solvents, drawbacks whereby the substrate is degraded as a result of ultraviolet rays are absent, and weatherability is also excellent.

TABLE 1

| | | | Surface resistance | | Light transmittance | | |
|---|---|---|---|---|---|---|---|
| | Flexural | Moisture | (Ω/square) | | % | | Appearance |
| | Modulus | Absorbance | Before heat | After heat | Before heat | After heat | After heat |
| | (kg/mm²) | (%) | treatment | treatment | treatment | treatment | treatment |
| Working | 65 | <0.01 | 36 | 36 | 85 | 85 | No change |
| Example 1 | | | | | | | |
| Working | 65 | <0.01 | 36 | 36 | 85 | 85 | No change |
| Example 2 | | | | | | | |
| Working | 55 | <0.01 | 36 | 36 | 89 | 89 | No change |
| Example 3 | | | | | | | |
| Comparative | 300 | 0.5 | 53 | 218 | 73 | 56 | Clouded |
| Example 1 | | | | | | | |

As a result of using a transparent, fluorine-containing resin film as the base material in the transparent electroconductive film of the present invention, a display device could be obtained having excellent flexibility compared to one in which a conventional polymer film is used, and a curved display is possible when this transparent electroconductive film is used as the substrate in a liquid crystal display device. Since the transparent electroconductive film of the present invention contains a heat-resistant transparent, fluorine-containing resin film, the light transmittance of a liquid crystal display device that uses this transparent electroconductive film as a substrate is not affected by heat treatment, and drawbacks whereby the substrate film is degraded in the high-temperature process for fabricating the orientation film are absent. Furthermore, when an acid or alkali is used in electrode patterning and the like, the transparent electroconductive film of the present invention has excellent resistance to these solvents, drawbacks whereby the substrate is degraded as a result of ultraviolet rays are absent, and weatherability is also excellent. Since the moisture absorbance is less than 0.1%, it is difficult for moisture in the vacuum to affect the product, and the reliability of the display device is also enhanced.

As a result of using the transparent, fluorine-containing resin film provided with a transparent electroconductive layer and a transparent gas barrier layer according to the present invention as the transparent substrate for holding a display medium, it is possible to provide a flexible display device that has low elasticity, high heat resistance, solvent resistance, and low moisture absorbance, as well as excellent display characteristics, reliability, and manufacturing yield.

While particular embodiments of the present invention have been illustrated and described herein, the present invention should not be limited to such illustrations and descriptions. It should be apparent that changes and modifications may be incorporated and embodied as part of the present invention within the scope of the following claims.

The invention claimed is:

1. A transparent electroconductive film, comprising a laminate having a three-layered structure comprising a transparent, fluorine-containing resin film having at least one face and a transparent gas barrier layer disposed on said at least one face to form a transparent electroconductive layer.

2. The transparent electroconductive film according to claim 1, further comprising a surface treatment for enhancing adhesion on said at least one face of said transparent, fluorine-containing resin film.

3. A transparent electroconductive film, comprising a laminate having a three-layered structure comprising a transparent, fluorine-containing resin film having a first face and a second face, a transparent gas barrier layer disposed on said first face, and a transparent electroconductive layer disposed on second said face.

4. The transparent electroconductive film according to claim 3, further comprising a surface treatment for enhancing adhesion on both said first and second faces of said transparent, fluorine-containing resin film.

5. The transparent electroconductive film according to claim 4, further comprising a primer layer on said surface-treated face of said transparent, fluorine-containing resin film.

6. The transparent electroconductive film according to claim 3, characterized in having a flexural modulus of 1 to 100 kg/mm².

7. The transparent electroconductive film according to claim 3, characterized in having light transmittance of 80% or higher at a wavelength of 550 nm after heat treatment, and in having no change in appearance due to heat treatment.

8. The transparent electroconductive film according to claim 3, characterized in that the moisture absorbance of said transparent, fluorine-containing resin film is 0.1% or less.

9. A display device having a structure in which a display medium between transparent substrates, said display device characterized in that at least one of the transparent substrates comprises the electroconductive film according to claim 3.

10. The display device according to claim 9, characterized in that the display medium comprises liquid crystal.

11. The display device according to claim 10, characterized in having a polymer structure between the substrates, for maintaining a constant spacing between the substrates.

12. The display device according to claim 9, characterized in that the display medium has electrophoretic effects whereby non-transparent particles are shifted or rotated as a result of the application of a voltage, and the state of absorbance of external light changes.

13. The display device according to claim 9, characterized in that the display medium has electrodeposition effects whereby metal ionization/deposition is controlled in an electrolyte solution by means of a current injection, and the state of absorbance of external light changes.

14. The display device according to claim 9, characterized in that the display medium comprises an organic thin film or a resin film with a dispersed inorganic phosphor having electroluminescent effects whereby light is emitted as a result of a current injection or a voltage application.

15. A display device having a structure in which a display medium comprising a thin film is laminated on a transparent substrate, said display device characterized in that the transparent substrate comprises the transparent electroconductive film according to claim 3.
